(19) United States
(12) Patent Application Publication
(10) Pub. No.: US 2024/0280912 A1
(43) Pub. Date: Aug. 22, 2024

(54) METHOD FOR MEASURING PHOTOMASKS FOR SEMICONDUCTOR LITHOGRAPHY

(71) Applicant: Carl Zeiss SMT GmbH, Oberkochen (DE)

(72) Inventors: Steffen Steinert, Jena (DE); Susanne Toepfer, Gleina-Baumersroda (DE); Carsten Schmidt, Jena (DE)

(21) Appl. No.: 18/651,759

(22) Filed: May 1, 2024

Related U.S. Application Data
(63) Continuation of application No. PCT/EP2022/082325, filed on Nov. 17, 2022.

(30) Foreign Application Priority Data
Nov. 18, 2021 (DE) 102021130149.1

(51) Int. Cl. G03F 7/00; G03F 1/84

(52) U.S. Cl. CPC G03F 7/705; G03F 1/84; G03F 7/70033

(57) ABSTRACT

A method for measuring photomasks for semiconductor lithography, includes the following steps:
loading a photomask into a recording unit of a measuring apparatus,
recording images of individual measurement regions on the photomask by means of an image capturing unit,
comparing at least one recorded image of a measurement region with a simulated image of this measurement region using specific simulation parameters. In the process, the comparison of at least one of the recorded images with the corresponding simulated image is used to carry out an adjustment of at least one portion of the simulation parameters.

### CROSS REFERENCE TO RELATED APPLICATIONS

This application is a continuation of and claims benefit under 35 U.S.C. § 120 from PCT Application No. PCT/EP2022/082325, filed on Nov. 17, 2022, which claims priority from German Application No. DE 10 2021 130 149.1, filed on Nov. 18, 2021 The entire contents of each of these prior applications are incorporated herein by reference.

### TECHNICAL FIELD

This disclosure relates to a method for measuring photomasks for semiconductor lithography, in particular a so-called die-to-database measurement.

### BACKGROUND

A method and a measuring apparatus in which such a method can be used of this kind are disclosed in the German patent application DE 10 2017 115 240 A1, which originates from the applicant.

A sought-after, ideal mask design, what is known as the design clip, is the starting point of a die-to-database measurement. However, this ideal mask design—even if it could be produced in reality—would not become directly visible as a result of real imaging by means of a real—and error-afflicted—optical unit of the image capturing unit of an optical measuring apparatus.

What becomes visible in the real measurement of a mask is the result of a convolution of the mask geometry with the optical transfer function of the measuring apparatus. Thus, to arrive at a realistic assessment of the quality of the real mask following a measurement of the mask on a real measuring apparatus, it is necessary to produce a simulated image of an ideal mask by way of a simulation which is based on the knowledge of the mask design and the properties of the optical unit used in the measuring apparatus.

Following the measurement of a real mask, this simulated image is compared to the real image of the mask recorded in the measurement—the so-called aerial image—and so it is possible to assess the mask quality.

However, it is also possible within the scope of this simulation to take into account that an ideal mask cannot be produced on account of the process, and that instead there are properties of masks that are subject to a certain variation. Thus, the circumstances that it is not possible to produce an ideal mask and that a real mask therefore has deviation vis-a-vis the design clip in terms of some of its properties as a result of the production process should be taken into account by the simulation. By way of example, there will be deviations of the “critical dimensions”—that is to say the width of certain structures—from target values specified in the design clip. A similar statement applies to the quality of corners of the structure—experience has taught that the corners of structures in the design clip are formed slightly rounded on the real mask as a result of etching processes.

Thus, there is a set of simulation parameters which is included in the generation of the simulated image, but which does not reflect the relationships and properties of the measuring apparatus but the properties of the examined mask. The suitable choice of these simulation parameters has a significant influence on the quality of the simulation and hence on the quality of the measurement.

### SUMMARY

One object of the present disclosure is to specify a method in which the simulation parameters can be optimized to the effect of allowing the attainment of an improved quality of the simulation and hence an improved accuracy in the measurement of photomasks.

In one aspect, disclosed herein is a method for measuring photomasks for semiconductor lithography including the following steps:
loading a photomask into a recording unit of a measuring apparatus,
recording images of individual measurement regions on the photomask by means of an image capturing unit,
comparing at least one recorded image of a measurement region with a simulated image of this measurement region using specific simulation parameters.

Expressed differently, the degree of correspondence of the simulated image is ascertained. By way of example, the simulation parameters can be the critical dimension CD, corner rounding or reflection amplitudes. The aforementioned parameters are suitably chosen to prevent a simulation error from arising as a result of an incorrect choice of the simulation parameters.

According to certain embodiments, the comparison of at least one of the recorded images with the corresponding simulated image is used to carry out an adjustment of at least one portion of the simulation parameters, in order to improve the quality of the simulation.

In particular, a renewed simulation with adjusted simulation parameters can be carried out if a certain threshold value for the quality of the simulation for the corresponding measurement region is undershot.

In the process, what is known as a merit function can be used to assess the quality of the simulation.

Furthermore, it would be possible to calculate the maximum pixel intensity deviation between measurement and simulation and perform a comparison with an empirically determined threshold value for the purposes of assessing the quality of the simulation. Likewise, edge regions could be weighted more strongly in a difference image for the purposes of assessing the quality of the simulation.

In an advantageous variant, the adjustment of the simulation parameters can be additionally or alternatively carried out on the basis of a preliminary measurement of defined exemplary measurement regions.

In this case, the preliminary measurement can be implemented during a thermal settling time of the mask in the recording unit. In this context, the thermal settling tine should be understood to mean the period of time which starts with loading the mask into the measuring apparatus and which ends as soon as a state is attained in which the rate of change of the mask geometry on account of the temperature differences has dropped below a certain threshold value.

In this case, measurement and determination of parameters can be carried out on a plurality of exemplary measurement regions (five, for example) on the real mask. The parameter sets per exemplary measurement region obtained thus are subsequently buffer stored and made available to the simulator.

In this case, the selection of the exemplary measurement regions depends inter alia on the structure of the mask to be measured. Expressed differently, the exemplary measurement regions are selected in advance using criteria that depend on the structures prevalent on the real mask. Furthermore, the exemplary measurement regions may also comprise different parameter sets—and not only different parameter values.

In this case, certain embodiments of the method are based on the discovery that measurement structure-specific, manufacturing process-dependent and mask position-related process deviations may lead to significantly more than one simulation parameter set being required in order to generate, for all measurement structures on a mask and by way of the simulation, reference images with a sufficiently high quality for a precise registration measurement.

The fact that the geometry of the real mask changes over time during the aforementioned preliminary measurement on account of the change in temperature can be neglected, especially also on account of the short measurement time required for the preliminary measurement.

Then, a respectively suitable parameter set for the region examined in each case can be selected in advance for the evaluation of the real measurement by virtue of the measured region being assigned to the fitting exemplary measurement region on account of the prevalent structures therein.

Here, it is naturally advantageous if the exemplary measurement regions are defined on the basis of the structures on the mask design.

As a result of ascertained parameter sets and/or exemplary measurement regions being stored and kept available for subsequent measurements of other photomasks, it is possible to gainfully utilize, optionally also by using artificial intelligence, the discoveries from the measurement of one mask for subsequent measurements on other masks as well.

Other aspects, features, and advantages follow.

### DESCRIPTION OF DRAWINGS

FIG. 1 is a flow chart for the steps of one embodiment of the measurement method.

### DETAILED DESCRIPTION

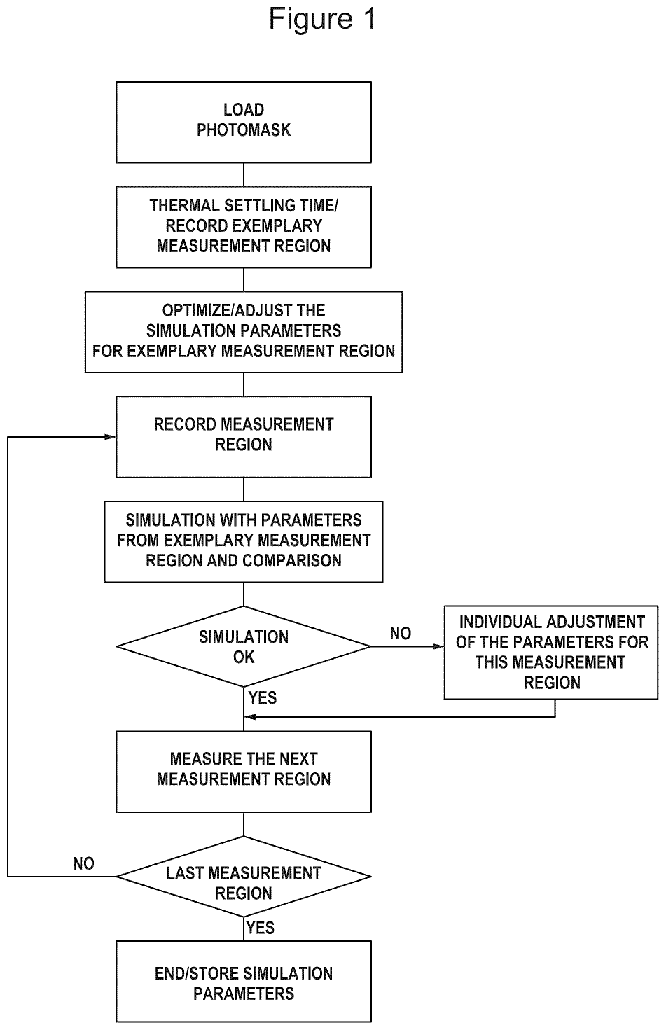

FIG. 1 illustrates an exemplary procedure of the measuring method using a flowchart. In this case, a photomask is loaded into a recording unit of a measuring apparatus in a first step; this is followed by the thermal settling time, usually of the order of 10-20 minutes, during which the photomask assumes the ambient temperature. Exemplary measurement regions on the mask defined in advance on the basis of the design clip are already recorded during this period of time. In this case, the preliminary definition of the exemplary measurement regions to be recorded can be implemented starting from the design clip, in such a way that regions that are representative for the mask design or subsequent chip design are selected as exemplary measurement regions. Thus, the exemplary measurement regions are defined in advance on the basis of the structure of the design clip.

Expressed differently, a suitable subset, in particular the smallest possible subset of exemplary measurement regions is selected from the totality of possible measurement regions, for which subset the simulation parameters are ascertained automatically before the actual start of the measurement. In this way, a set of various simulation parameters which are available for the actual measurement and which can be used arises. This may also be considered to be an automatic calibration phase during the mask heating time. This period of time is usable for the calibration of the simulation model, that is to say for the determination of the simulation parameters, since changes in length during the settling time have only a minor influence on the determined simulation parameters. This allows the process duration to be significantly reduced while having a sufficient accuracy of the measurement, especially for subsequent registration measurements.

The simulation parameters are adjusted in the next step on the basis of the recorded exemplary measurement regions. These simulation parameters are used in the next step for the determination of the simulated image. The simulated image in turn is used, following the measurement of the mask measurement region by measurement region, for a comparison with the respectively examined measurement region.

Whether or not the simulation satisfies the specified criteria is then decided on the basis of this comparison. Should this not be the case, a renewed adjustment of the simulation parameters is carried out using the real measured measurement region and a new evaluation is carried out on the basis of the simulation which has been optimized in this way. However, if the check yields that the simulation meets the set requirements, that is to say, in particular, a merit function assumes a value below a threshold value set in advance, the measurement procedure is continued by measuring the next measurement region. The measurement is complete as soon as the last measurement region to be measured has been measured and simulated.

A certain self-learning functionality of the method can be attained by virtue of the ascertained, adjusted simulation parameters being saved in a memory unit for future measurements.

In this case, the described adjustment of the simulation parameters need not necessarily be implemented both during the thermal settling time and the real measurement. It may also be carried out exclusively in one of the two periods of time, that is to say during the thermal settling time or during the real measurement of the mask.

The method is suitable for application for photomasks that are used for various wavelength ranges, for example also masks for the EUV wavelength range, that is to say in particular also for a wavelength range of the order of 13.5 nm. In this case, use is typically made of a measuring apparatus that likewise operates in this wavelength range and the optical components of which are in the form of mirrors, especially multilayer mirrors.

Additional embodiments are within the scope of the following claims.

What is claimed is:

1. A method for measuring photomasks for semiconductor lithography, comprising:
loading a photomask into a recording unit of a measuring apparatus,
recording images of individual measurement regions on the photomask with an image capturing unit,
comparing at least one recorded image of a measurement region with a simulated image of this measurement region using specific simulation parameters,
wherein the comparison of at least one of the recorded images with the corresponding simulated images is used to carry out an adjustment of at least one portion of the simulation parameters, and the simulation parameters are adjusted on the basis of a preliminary measurement of defined exemplary measurement regions.

2. The method of claim 1, wherein
a renewed simulation with adjusted simulation parameters is carried out if a certain threshold value for the quality of the simulation for the corresponding measurement region is undershot.

3. The method of claim 1, wherein
a merit function is used to assess the quality of the simulation.

4. The method of claim 2, wherein
a merit function is used to assess the quality of the simulation.

5. The method of claim 1, wherein
the preliminary measurement is implemented during a thermal settling time of the mask in the recording unit.

6. The method of claim 1, wherein
the exemplary measurement regions are defined on the basis of the structures on the mask design.

7. The method of claim 1, wherein
different parameter sets are ascertained for at least two exemplary measurement regions.

8. The method of claim 1, wherein
ascertained parameter sets and/or exemplary measurement regions are stored and kept available for subsequent measurements of other photomasks.

9. The method of claim 1, wherein
electromagnetic radiation with a wavelength in the EUV range is used for image recording purposes.

10. The method of claim 9, wherein
the wavelength of the utilized radiation is of the order of 13.5 nm.

11. The method of claim 2, wherein
the preliminary measurement is implemented during a thermal settling time of the mask in the recording unit.

12. The method of claim 11, wherein
the exemplary measurement regions are defined on the basis of the structures on the mask design.

13. The method of claim 12, wherein
different parameter sets are ascertained for at least two exemplary measurement regions.

14. The method of claim 13, wherein
ascertained parameter sets and/or exemplary measurement regions are stored and kept available for subsequent measurements of other photomasks.

15. The method of claim 14, wherein
electromagnetic radiation with a wavelength in the EUV range is used for image recording purposes.

16. The method of claim 5, wherein
the exemplary measurement regions are defined on the basis of the structures on the mask design.

17. The method of claim 16, wherein
different parameter sets are ascertained for at least two exemplary measurement regions.

18. The method of claim 17, wherein
electromagnetic radiation with a wavelength in the EUV range is used for image recording purposes.

19. The method of claim 6, wherein
different parameter sets are ascertained for at least two exemplary measurement regions.

20. The method of claim 19, wherein
electromagnetic radiation with a wavelength in the EUV range is used for image recording purposes.
